(19) United States
(12) Patent Application Publication
(10) Pub. No.: US 2026/0129816 A1
(43) Pub. Date: May 7, 2026

(54) ELECTRONIC DEVICE

(71) Applicant: CARUX TECHNOLOGY PTE. LTD., SINGAPORE (SG)

(72) Inventors: Yung-Kan Chen, Tainan (TW); Ching-Ming Chen, Tainan (TW); Hui-Chuan Huang, Tainan (TW)

(73) Assignee: CARUX TECHNOLOGY PTE. LTD., SINGAPORE (SG)

(21) Appl. No.: 19/348,819

(22) Filed: Oct. 3, 2025

(30) Foreign Application Priority Data
Nov. 4, 2024 (CN) 202411560331.0

(51) Int. Cl. H05K 7/20

(52) U.S. Cl. CPC H05K 7/20972

(57) ABSTRACT

The disclosure provides an electronic device including a panel, a protective plate, and a housing. The panel has a first surface and a second surface. The protective plate is disposed above the panel and has a third surface and a fourth surface. The housing includes a first side cover and a second side cover. The third surface of the protective plate is attached to the second surface of the panel, and there is a first channel between the panel and the first side cover, so that a first gas flow flows between the first surface and the first side cover. The fourth surface of the protective plate is close to the second side cover, and there is a second channel between the protective plate and the second side cover, so that a second gas flow contacts the fourth surface of the protective plate.

### CROSS-REFERENCE TO RELATED APPLICATION

This application claims the priority benefit of China application serial no. 202411560331.0, filed on Nov. 4, 2024. The entirety of the above-mentioned patent application is hereby incorporated by reference herein and made a part of this specification.

### BACKGROUND

### Technical Field

The disclosure relates to an electronic device, and more particularly to an electronic device with a heat dissipation effect.

### Description of Related Art

Head-up display (HUD) is the mainstream for future car cabin display. The high brightness specifications of the head-up display create a high temperature environment, which may cause damage or melting of components in severe cases. Furthermore, due to the high power operation of the head-up display and exposure to sunlight, the panel may also experience serious overheating, which causes serious product failure. Therefore, how to reduce or control the impact of the heat of the head-up display on the display quality, safety, and reliability of the high power head-up display is still an important topic in the art.

### SUMMARY

The disclosure provides an electronic device with a heat dissipation effect.

According to an embodiment of the disclosure, an electronic device includes a panel, a protective plate, and a housing. The panel has a first surface and a second surface. The protective plate is disposed above the panel and has a third surface and a fourth surface. The housing includes a first side cover and a second side cover. The third surface of the protective plate is attached to the second surface of the panel, and there is a first channel between the panel and the first side cover, so that a first gas flow flows between the first surface and the first side cover. The fourth surface of the protective plate is close to the second side cover, and there is a second channel between the protective plate and the second side cover, so that a second gas flow contacts the fourth surface of the protective plate.

Based on the above, in the embodiment of the disclosure, there is the first channel between the panel and the first side cover, so that the first gas flow may flow between the first surface of the panel and the first side cover, and there is the second channel between the protective plate and the second side cover, so that the second gas flow may contact the fourth surface of the protective plate. In this way, heat is taken away from upper and lower sides (or front and back sides) of the panel in an enveloping convection heat dissipation manner, so that the electronic device of the disclosure can achieve a uniform heat dissipation and temperature reduction effect.

In order for the features and advantages of the disclosure to be more comprehensible, the following specific embodiments are described in detail in conjunction with the drawings.

### BRIEF DESCRIPTION OF THE DRAWINGS

FIG. 1A is a schematic cross-sectional view of an electronic device according to an embodiment of the disclosure.

FIG. 1B is a schematic top view of a flow divider of the electronic device of FIG. 1A.

FIG. 1C is a schematic partial three-dimensional view of a flow divider and a flow dividing assembly of the electronic device of FIG. 1A.

FIG. 2 is a schematic cross-sectional view of an electronic device according to another embodiment of the disclosure.

FIG. 3 is a schematic cross-sectional view of an electronic device according to another embodiment of the disclosure.

FIG. 4 is a schematic cross-sectional view of an electronic device according to another embodiment of the disclosure.

FIG. 5 is a schematic cross-sectional view of an electronic device according to another embodiment of the disclosure.

FIG. 6 is a schematic cross-sectional view of an electronic device according to another embodiment of the disclosure.

FIG. 7 is a schematic cross-sectional view of an electronic device according to another embodiment of the disclosure.

### DESCRIPTION OF THE EMBODIMENTS

In addition, relative terms such as “below” or “bottom portion” and “above” or “top portion” may be used in the embodiments to describe the relative relationship of an element to another element in the drawings. It should be understood that if a device in the drawings is turned upside down, elements described as “below”will become elements described as “above”.

In some embodiments of the disclosure, terms related to bonding and connection, such as “connection” and “interconnection”, unless otherwise defined, may refer to two structures that are directly in contact or may also refer to two structures that are not directly (indirectly) in contact, wherein there is another structure provided between the two structures. Also, the terms related to bonding and connection may also include the case where two structures are both movable or two structures are both fixed.

It should be understood that when an element or a film layer is referred to as being “on” another element or film layer or “connected to” another element or film layer, the element may be directly on the other element or film layer or directly connected to the other element or film layer, or there is an element or a film layer inserted between the two (indirect case). In contrast, when an element is referred to as being “directly on” another element or film layer or “directly connected to” another element or film layer, there is no element or film layer inserted between the two.

The terms “about”, “equal to”, “equivalent” or “same”, “substantially”, or “roughly” are generally interpreted as within 10% of a given value or range, or interpreted as within 5%, 3%, 2%, 1%, or 0.5% of the given value or range.

It should be noted that in the following embodiments, the technical features of several different embodiments may be replaced, reorganized, and mixed to complete other embodiments without departing from the spirit of the disclosure.

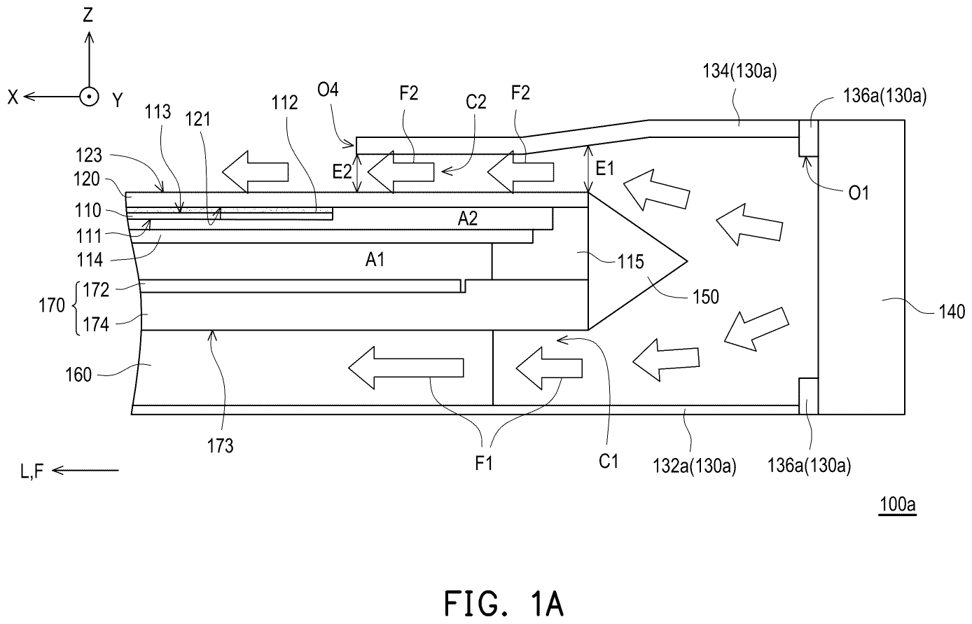

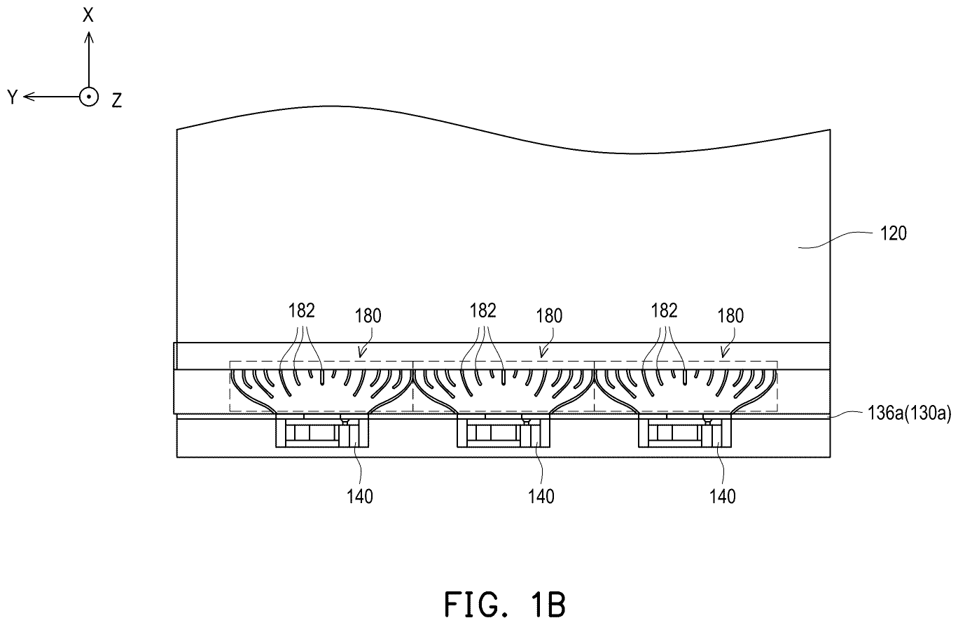

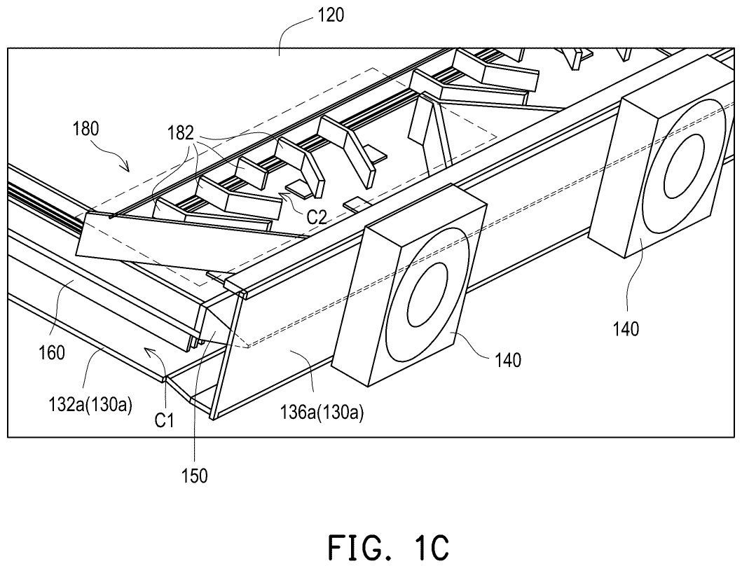

Please refer to FIG. 1A first. In the embodiment, an electronic device 100a includes a panel 110, a protective plate 120, and a housing 130a. The panel 110 has a first surface 111 and a second surface 113. The protective plate 120 is disposed above the panel 110 and has a third surface 121 and a fourth surface 123. The housing 130a includes a first side cover 132a and a second side cover 134. The third surface 121 of the protective plate 120 is attached to the second surface 113 of the panel 110, and there is a first channel C1 between the panel 110 and the first side cover 132a, so that a first gas flow F1 flows between the first surface 111 and the first side cover 132a. The fourth surface 123 of the protective plate 120 is close to the second side cover 134, and there is a second channel C2 between the protective plate 120 and the second side cover 134, so that a second gas flow F2 contacts or blows against the fourth surface 123 of the protective plate 120.

In the embodiment, “attachment” may refer to direct attachment of two assemblies or that there is at least one adhesive layer between the two assemblies, so that there is no gap between the two assemblies. The panel 110 of the embodiment may be fixed onto the third surface 121 of the protective plate 120 through an adhesive layer 112. In an embodiment, the adhesive layer 112 may be, for example, an optical clear adhesive (OCA), an optical clear resin (OCR), other suitable transparent materials, or a combination of the above, but not limited thereto. In the embodiment, the material of the protective plate 120 is, for example, glass, polyethylene terephthalate (PET), polyimide (PI), or other suitable materials. Furthermore, the electronic device 100a of the embodiment further includes an optical film sheet 114 and a middle frame 115. In an embodiment, the optical film sheet 114 may be, for example, an optical brightness enhancement film, a diffusion sheet, a prism sheet, or a combination of the above and may adjust an optical effect of a light beam. The panel 110 passes through the middle frame 115 and is disposed above the optical film sheet 114, wherein the middle frame 115 may carry the optical film sheet 114, and the protective plate 120 is disposed and supported on the middle frame 115. In an embodiment, the material of the middle frame 115 may be, for example, a light shielding material, but not limited thereto.

Furthermore, the electronic device 100a further includes a light source module 170 disposed between the first side cover 132a and the first surface 111 of the panel 110 to provide the panel 110 with a required surface light source. In the embodiment, the light source module 170 includes a backlight source 172 and a back plate 174. In some embodiments, the light source module 170 may be a direct-type light source module or an edge-type light source module, but not limited thereto. In an embodiment, the backlight source 172 may include, for example, a light emitting diode, a light guide plate, a reflective sheet, and an optical film sheet, but not limited thereto. In addition, the electronic device 100a of the embodiment may further include a heat dissipation fin 160 disposed between the first side cover 132a and the first surface 111 of the panel 110, wherein on a cross section of the electronic device 100a, an extension direction L of the heat dissipation fin 160 is the same as a flow direction F of the first gas flow F1. In an embodiment, the panel 110, the optical film sheet 114, the protective plate 120, and the light source module 170 may be regarded as a display module, wherein the fourth surface 123 of the protective plate 120 is a front side of the display module, and a surface 173 of the light source module 170 away from the panel 110 may be regarded as a back side of the display module.

In the embodiment, there is a first cavity A1 between the optical film sheet 114 and the light source module 170, and there is a second cavity A2 between the protective plate 120 and the optical film sheet 114. Since the light source module 170 generates a large amount of heat during operation, the heat needs to be insulated through the first cavity A1 to reduce conduction of the heat toward the optical film sheet 114. In this way, the heat generated by the light source module 170 may be concentrated on the heat dissipation fin 160 below for heat dissipation. The second cavity A2 is located between the panel 110 and the optical film sheet 114, wherein the panel 110 also generates heat during operation. Therefore, the heat generated by the panel 110 is blocked through providing the second cavity A2. In short, the first cavity A1 and/or the second cavity A2 may be used to reduce damage of the optical film sheet 114 caused by high temperature, and may also make it easier for the heat to be taken away by the first gas flow F1 and/or the second gas flow F2. In an embodiment, the first cavity A1 and the second cavity A2 may respectively contain air. In an embodiment, the first cavity A1 and the second cavity A2 may be respectively filled with or provided with a material or a component with a thermal conductivity lower than that of air.

Please refer to FIG. 1A again. In the embodiment, the housing 130a further includes a third side cover 136a connecting the first side cover 132a and the second side cover 134. On a cross section, a rough extension direction of the first side cover 132a is parallel to a rough extension direction of the second side cover 134, and an extension direction of the third side cover 136a is perpendicular to the extension directions of the first side cover 132a and the second side cover 134, the first side cover 132a is close to the panel 110, and the second side cover 134 is close to the light source module 170. In an embodiment, the first side cover 132a may be regarded as a lower cover, the second side cover 134 may be regarded as an upper cover, and the third side cover 136a may be regarded as a side cover. In an embodiment, the second side cover 134 may also be regarded as an extension of a fan frame. Furthermore, the electronic device 100a of the embodiment further includes a first fan 140, and the housing 130a further has a first opening O1, wherein the first fan 140 is disposed corresponding to the first opening O1 to form at least one of the first gas flow F1 and the second gas flow F2. In addition, the electronic device 100a may further include a flow divider 150 disposed adjacent to the first fan 140, wherein a gas flow generated by the first fan 140 blows along an X direction, and an air outlet of the first fan 140 corresponds to a top end of the flow divider 150 to divide the gas flow in the Z direction into the first gas flow F1 and the second gas flow F2. In some embodiments, the top end of the flow divider 150 may be pointed, arced, or flat, but not limited thereto. In the embodiment, the third side cover 136a has a first opening O1, and the first fan 140 is disposed corresponding to the first opening O1, which means that the embodiment adopts side air intake, and the gas flow in the Z direction generated by the first fan 140 is divided by the flow divider 150 to form the first gas flow F1 and the second gas flow F2. In short, the embodiment adopts a fan (that is, the first fan 140), and the gas flow generated by the first fan 140 may be divided into an upper gas flow (that is, the second gas flow F2) and a lower gas flow (that is, the first gas flow F1) through the flow divider 150 to form an enveloping flow field, so as to not only improve the efficiency of the first fan 140, but also uniformly dissipate heat from the front and back sides of the display module.

In an embodiment, the first fan 140 may, for example, use a fluid dynamic bearing (FDB), a magnetic system (MS) bearing, or a vaporization (VAPO) bearing to reduce operation noise. The hydrodynamic lubrication of the fluid dynamic bearing generates a thin fluid film, so that a bearing sleeve is contactless (or contact is minimized), thereby reducing operation noise. For the magnetic system bearing and the vaporization bearing, rotor weights are supported on magnetic levitation tracks, so that bearing sleeves are contactless (or contact is minimized), thereby reducing operation noise.

Next, please refer to FIG. 1A, FIG. 1B, and FIG. 1C at the same time. In the embodiment, the electronic device 100a may also include multiple flow dividing assemblies 180. Each flow dividing assembly 180 includes multiple flow dividing plates 182 dispersed from each other, wherein the flow dividing assembly 180 may be disposed corresponding to the first fan 140 and disposed on a flow path of the second gas flow F2, and the flow dividing plate 182 is used to divide the second gas flow F2 in a Y direction, thereby generating a uniform gas flow on an XY plane. In an embodiment, the flow dividing plate 182 of the flow dividing assembly 180 may also divide the second gas flow F2 in the X direction, thereby generating a uniform gas flow on the XY plane. Through providing the flow dividing plate 182, the second gas flow F2 may be dispersed left and right, so that a smaller number of fans may be used to blow over a larger area to improve a heat dissipation effect in a more efficient and economical manner. In an embodiment, the flow dividing plate 182 may also be disposed on a flow path of the first gas flow F1 to divide the first gas flow F1 flowing through the first channel C1. In an embodiment, the flow dividing plate 182 may also be disposed on the flow path of the second gas flow F2 and/or the flow path of the first gas flow F1 at the same time to divide the second gas flow F2 flowing through the second channel C2 and the first gas flow F1 flowing through the first channel C1. In some embodiments, one flow dividing assembly 182 may correspond to one fan (see FIG. 1B), but not limited thereto. In other embodiments, multiple flow dividing assemblies 180 may correspond to one fan (not shown), but not limited thereto.

Please refer to FIG. 1A again. In the embodiment, a cross-sectional area of an air entrance E1 of the second channel C2 is greater than a cross-sectional area of an air outlet E2, that is, the design of high inlet and low outlet is adopted, thereby increasing the gas flow speed flowing through the front side of the display module, that is, increasing the speed of a planar flow field to improve the heat dissipation effect. In addition, the housing 130a of the embodiment further has a fourth opening O4 to expose at least part of the protective plate 120, which means that a part of the fourth surface 123 of the protective plate 120 is exposed.

In short, in the embodiment, there is the first channel C1 between the panel 110 and the first side cover 132a, so that the first gas flow F1 flows between the first surface 111 of the panel 110 and the first side cover 132a, and there is the second channel C2 between the protective plate 120 and the second side cover 134, so that the second gas flow F2 contacts the fourth surface 123 of the protective plate 120. In this way, the surface of the display module may generate a uniform and stable flow field, thereby taking away the heat from the front and back sides of the display module in an enveloping convection heat dissipation manner, so that the electronic device 100a of the embodiment can achieve a uniform heat dissipation and temperature reduction effect. In addition, since the electronic device 100a of the embodiment may also be provided with the flow dividing assembly 180 having the flow dividing plate 182, the stable and uniform enveloping flow field may be generated with a smaller number of fans, which can solve the issues of overheating and non-uniform heat dissipation of the display module under high power in the prior art.

It should be noted that the following embodiments continue to use the reference numerals and some content of the foregoing embodiment, wherein the same reference numerals are adopted to represent the same or similar elements, and the description of the same technical content is omitted. Reference may be made to the foregoing embodiment for the description of the omitted part, which will not be repeated in the following embodiments.

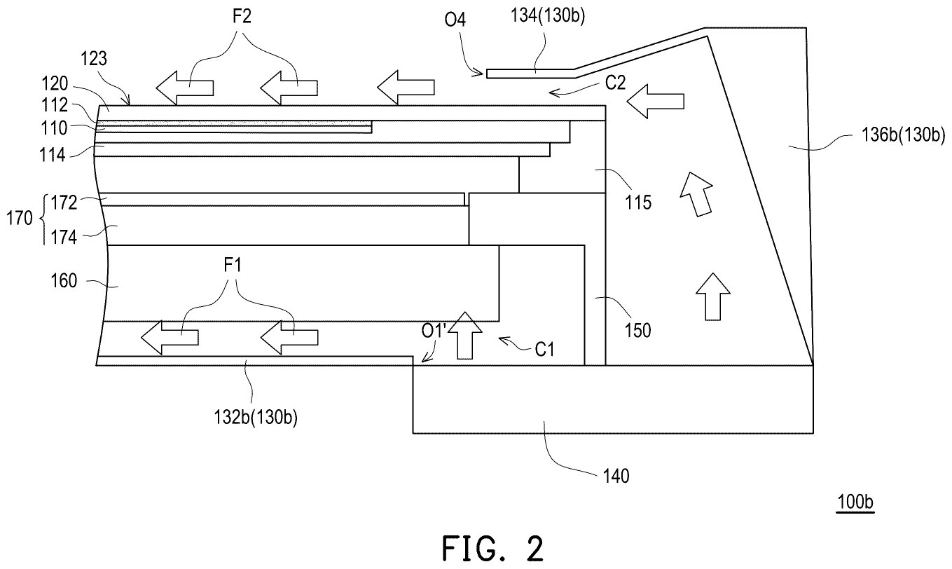

FIG. 2 is a schematic cross-sectional view of an electronic device according to another embodiment of the disclosure. Please refer to FIG. 1A and FIG. 2 at the same time. An electronic device 100b of the embodiment is similar to the electronic device 100a of FIG. 1A. The difference between the two is that in the embodiment, a first side cover 132b of a housing 130b has a first opening O1′, and the first fan 140 is disposed corresponding to the first opening O1′, which means that the embodiment adopts bottom air intake. Through providing the flow divider 150, an airflow of the first fan 140 is divided into the first gas flow F1 and the second gas flow F2 to form an enveloping flow field to uniformly dissipate heat from the front and back sides of the display module, so that the electronic device 100b of the embodiment has a good heat dissipation effect. In an embodiment, the first fan 140 may also be replaced by an air conditioning system in a vehicle body, wherein a flow rate may be adjusted through providing air holes/air grilles.

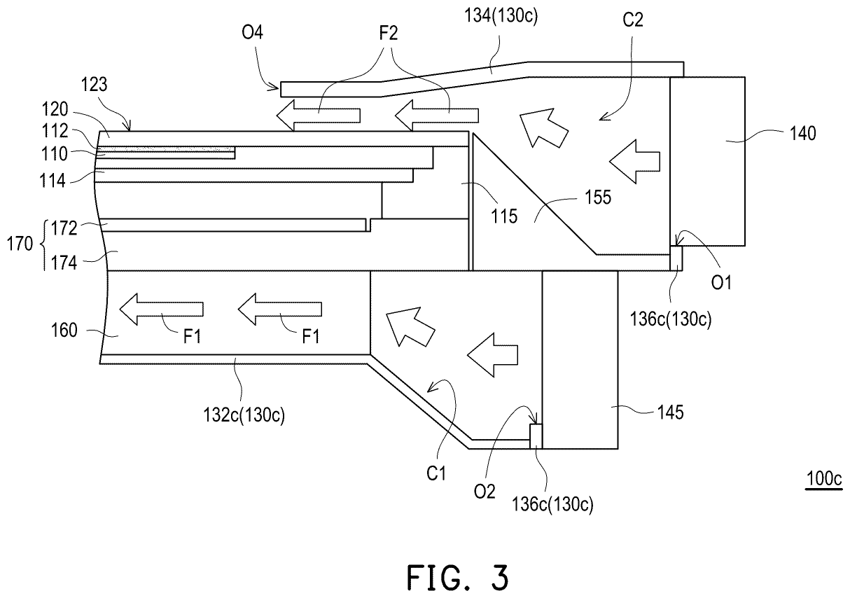

FIG. 3 is a schematic cross-sectional view of an electronic device according to another embodiment of the disclosure. Please refer to FIG. 1A and FIG. 3 at the same time. An electronic device 100c of the embodiment is similar to the electronic device 100a of FIG. 1A. The difference between the two is that in the embodiment, the electronic device 100c further includes a second fan 145, and a housing 130c further has a second opening O2, wherein the second fan 145 is disposed corresponding to the second opening O2 to form the first gas flow F1. Specifically, in the embodiment, a third side cover 136c of the housing 130c has the first opening O1 adjacent to the second side cover 134, and the first fan 140 is disposed corresponding to the first opening O1 to generate the second gas flow F2 in a side air intake manner. Furthermore, the third side cover 136c of the housing 130c of the embodiment has the second opening O2 adjacent to the first side cover 132c, and the second fan 145 is disposed corresponding to the second opening O2 to generate the first gas flow F1 in a side air intake manner. Here, the electronic device 100c does not have a flow divider, but has a partition 155, wherein the partition 155 is located between the first opening O1 and the second opening O2 to separate the first gas flow F1 and the second gas flow F2, so that the first gas flow F1 and the second gas flow F2 both have good flow directions to reduce the possibility of turbulence and improve heat dissipation efficiency. In an embodiment, the flow divider may be disposed in the first channel C1 and/or the second channel C2 to divide the gas flow. In an embodiment, the flow divider and a flow dividing assembly having a flow dividing plate may also be disposed in the first channel C1 and/or the second channel C2 to divide the gas flow.

In short, in the embodiment, the second gas flow F2 flowing through the second channel C2 and the first gas flow F1 flowing through the first channel C1 are respectively generated through the independent first fan 140 and second fan 145, thereby forming an enveloping flow field to uniformly dissipate heat from the front and back sides of the display module, so that the electronic device 100c of the embodiment has an improved heat dissipation effect.

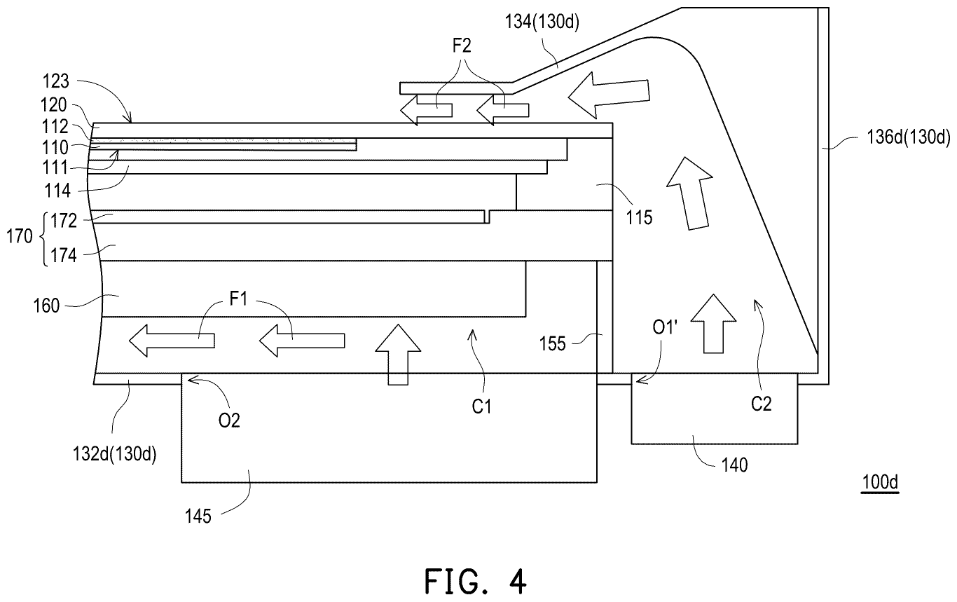

FIG. 4 is a schematic cross-sectional view of an electronic device according to another embodiment of the disclosure. Please refer to FIG. 1A and FIG. 4 at the same time. An electronic device 100d of the embodiment is similar to the electronic device 100a of FIG. 1A. The difference between the two is that in the embodiment, the electronic device 100d further includes a second fan 145, and a housing 130d further includes a second opening O2, wherein the second fan 145 is disposed corresponding to the second opening O2 to form the first gas flow F1. Specifically, in the embodiment, a first side cover 132d of the housing 130d has a first opening O1′ and the second opening O2 at the same time. The first fan 140 is disposed corresponding to the first opening O1′ and generates the second gas flow F2 in a bottom air intake manner, and the second fan 145 is disposed corresponding to the second opening O2 and generates the first gas flow F1 in a bottom air intake manner. Here, the electronic device 100d does not have a flow divider, but has a partition 155 located between the first gas flow F1 and the second gas flow F2 to separate the first gas flow F1 and the second gas flow F2, so that the first gas flow F1 and the second gas flow F2 both have good flow directions to reduce the possibility of turbulence and improve heat dissipation efficiency.

In short, in the embodiment, the second gas flow F2 flowing through the second channel C2 and the first gas flow F1 flowing through the first channel C1 are respectively generated through the independent first fan 140 and second fan 145, thereby forming an enveloping flow field to uniformly dissipate heat from the front and back sides of the display module, so that the electronic device 100d of the embodiment has a good heat dissipation effect.

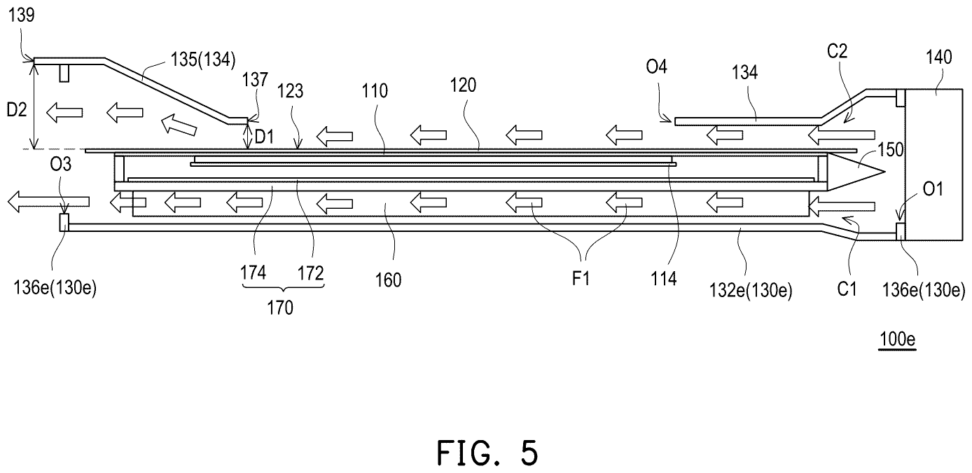

FIG. 5 is a schematic cross-sectional view of an electronic device according to another embodiment of the disclosure. Please refer to FIG. 1A and FIG. 5 at the same time. An electronic device 100e of the embodiment is similar to the electronic device 100a of FIG. 1A. The difference between the two is that in the embodiment, a side cover body of the second side cover 134 further away from the first fan 140 may be regarded as an air receiving plate 135, a housing 130e further has a third opening O3, and the air receiving plate 135 is disposed adjacent to the third opening O3. Specifically, in the embodiment, the air receiving plate 135 has an air inlet 137 and an air outlet 139, wherein an aperture D1 of the air inlet 137 is smaller than an aperture D2 of the air outlet 139, so that a surface wind speed flowing through the fourth surface 123 of the protective plate 120 may be increased.

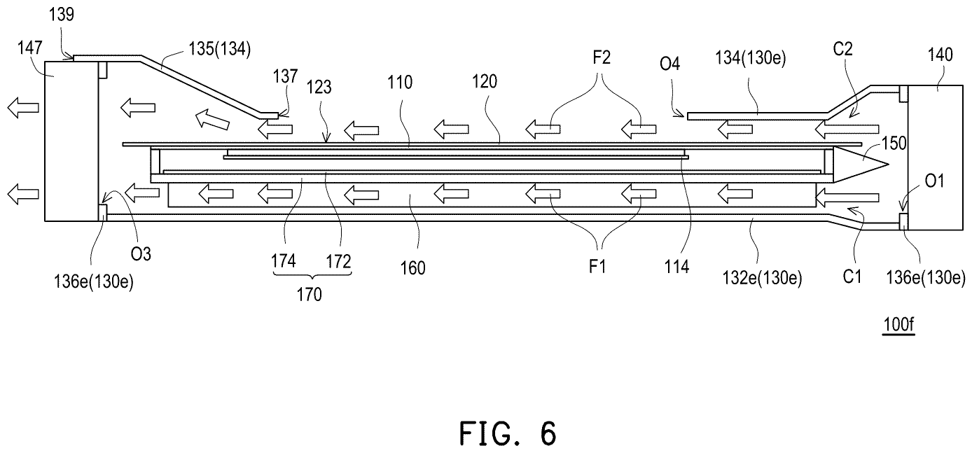

FIG. 6 is a schematic cross-sectional view of an electronic device according to another embodiment of the disclosure. An electronic device 100f of the embodiment is similar to the electronic device 100e of FIG. 5. The difference between the two is that in the embodiment, the electronic device 100f further includes a third fan 147, and the third fan 147 is disposed corresponding to the third opening O3 to discharge at least one of the first gas flow F1 and the second gas flow F2. Here, the third fan 147 may be regarded as an exhaust fan, which may discharge the first gas flow F1 and/or the second gas flow F2. Since the third fan 147 is disposed at the air outlet 139 of the air receiving plate 135, air is drawn outward to form a negative pressure effect, which may increase a wind speed flowing through the fourth surface 123 of the protective plate 120 and the surface of the heat dissipation fin 160, which means that the wind speed of the enveloping flow field is increased, thereby generating an improved temperature reduction effect, so that the temperature of the display module may be reduced. In other words, providing the third fan 147 can improve the surface wind speed and heat dissipation capacity.

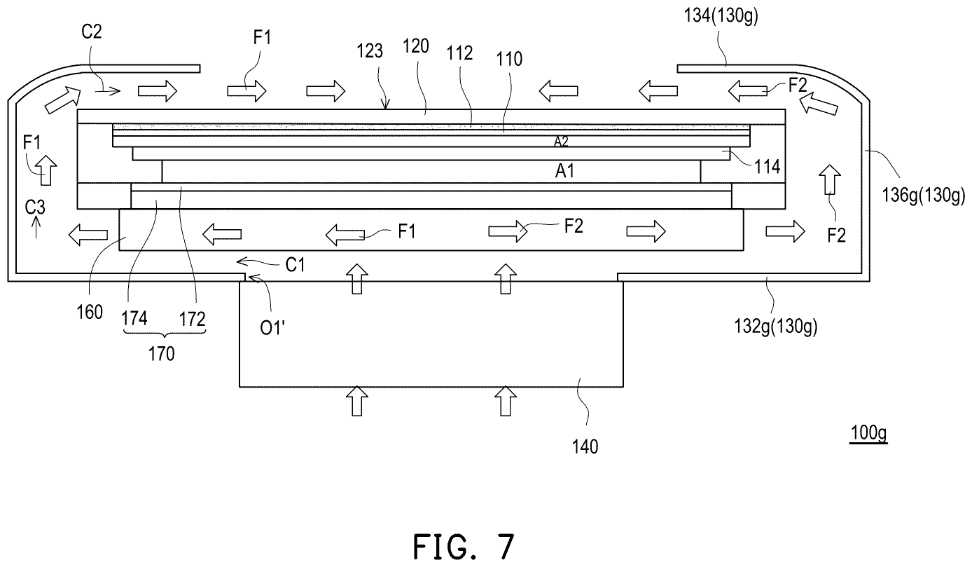

FIG. 7 is a schematic cross-sectional view of an electronic device according to another embodiment of the disclosure. Please refer to FIG. 1A and FIG. 7 at the same time. An electronic device 100g of the embodiment is similar to the electronic device 100a of FIG. 1A. The difference between the two is that in the embodiment, no flow divider is adopted, and instead a housing 130g is designed to generate an enveloping flow field. Specifically, in the embodiment, a first side cover 132g, a third side cover 136g, and the second side cover 134 form an enveloping shell. There is the first channel C1 between the panel 110 and the first side cover 132g, there is a third channel C3 between the third side cover 136g and the display module, and there is the second channel C2 between the protective plate 120 and the second side cover 134. The first side cover 132g has a first opening O1′, and the first fan 140 is disposed corresponding to the first opening O1′, which means that the embodiment adopts bottom air intake. Through the design of the housing 130g, the airflow of the first fan 140 may be divided into the first gas flow F1 (that is, the gas flow to the left) and the second gas flow F2 (that is, the gas flow to the right) to form an enveloping flow field to uniformly dissipate heat from the front and back sides of the display module.

In summary, in the embodiment of the disclosure, there is the first channel between the panel and the first side cover, so that the first gas flow may flow between the first surface of the panel and the first side cover, and there is the second channel between the protective plate and the second side cover, so that the second gas flow may contact the fourth surface of the protective plate. In this way, the heat is taken away from upper and lower sides (or the front and back sides) of the panel in the enveloping convection heat dissipation manner, so that the electronic device of the disclosure can achieve the uniform heat dissipation and temperature reduction effect.

What is claimed is:

1. An electronic device, comprising:
a panel, having a first surface and a second surface;
a protective plate, disposed above the panel and having a third surface and a fourth surface; and
a housing, comprising a first side cover and a second side cover, wherein the third surface of the protective plate is attached to the second surface of the panel, there is a first channel between the panel and the first side cover, so that a first gas flow flows between the first surface and the first side cover, the fourth surface of the protective plate is close to the second side cover, and there is a second channel between the protective plate and the second side cover, so that a second gas flow contacts the fourth surface of the protective plate.

2. The electronic device according to claim 1, further comprising:
a first fan, wherein the housing further has a first opening, and the first fan is disposed corresponding to the first opening to form at least one of the first gas flow and the second gas flow.

3. The electronic device according to claim 2, wherein the housing further comprises a third side cover connecting the first side cover and the second side cover, and the third side cover has the first opening.

4. The electronic device according to claim 2, wherein the first side cover of the housing has the first opening.

5. The electronic device according to claim 2, further comprising:
a second fan, wherein the housing further has a second opening, and the second fan is disposed corresponding to the second opening to form other one of the first gas flow and the second gas flow.

6. The electronic device according to claim 2, further comprising:
a third fan, wherein the housing further has a third opening, and the third fan is disposed corresponding to the third opening to discharge at least one of the first gas flow and the second gas flow.

7. The electronic device according to claim 2, wherein the housing further has a fourth opening exposing at least part of the protective plate.

8. The electronic device according to claim 2, further comprising:
a flow divider, located between the first fan and the first channel to form the first gas flow and the second gas flow.

9. The electronic device according to claim 1, further comprising:
a heat dissipation fin, disposed between the first side cover and the first surface of the panel, wherein an extension direction of the heat dissipation fin is the same as a flow direction of the first gas flow.

10. The electronic device according to claim 1, further comprising:
a light source module, disposed between the first side cover and the first surface of the panel.

11. The electronic device according to claim 10, wherein an extension direction of the first side cover is parallel to an extension direction of the second side cover, the first side cover is close to the panel, and the second side cover is close to the light source module.

12. The electronic device according to claim 10, further comprising:
an optical film sheet and a middle frame, wherein the panel passes through the middle frame and is disposed above the optical film sheet.

13. The electronic device according to claim 12, wherein there is a first cavity between the optical film sheet and the light source module, and there is a second cavity between the protective plate and the optical film sheet.

14. The electronic device according to claim 13, wherein the first cavity and the second cavity respectively contain air.

15. The electronic device according to claim 1, further comprising:
a plurality of flow dividing assemblies, wherein each of the flow dividing assemblies comprises a plurality of flow dividing plates dispersed from each other, and each of the flow dividing assemblies is disposed on a flow path of the first gas flow.

16. The electronic device according to claim 1, further comprising:
a plurality of flow dividing assemblies, wherein each of the flow dividing assemblies comprises a plurality of flow dividing plates dispersed from each another, and each of the flow dividing assemblies is disposed on a flow path of the second gas flow.

17. The electronic device according to claim 1, wherein the second channel has an air entrance and an air outlet, and a cross-sectional area of the air entrance is greater than a cross-sectional area of the air outlet.

18. The electronic device according to claim 1, wherein the housing further comprises a third side cover, the first side cover, the third side cover, and the second side cover form an enveloping shell, and there is a third channel between the third side cover and the panel.

19. The electronic device according to claim 1, wherein a side cover body of the second side cover is an air receiving plate, the air receiving plate has an air inlet and an air outlet, and an aperture of the air inlet is smaller than an aperture of the air outlet.

20. The electronic device according to claim 1, wherein the panel is fixed onto the third surface of the protective plate through an adhesive layer.
